(19) United States
(12) Patent Application Publication
(10) Pub. No.: US 2026/0047495 A1
(43) Pub. Date: Feb. 12, 2026

(54) SYSTEMS AND METHODS FOR 3D STACKING OF SEMICONDUCTOR DIES IN A FACE-TO-BACK STAGGERED PATTERN

(71) Applicant: Eridu Corporation, Saratoga, CA (US)

(72) Inventors: Ting-Kuang Chiang, Saratoga, CA (US); Liang Wang, Newark, CA (US)

(73) Assignee: Eridu Corporation, Saratoga, CA (US)

(21) Appl. No.: 19/295,686

(22) Filed: Aug. 10, 2025

Related U.S. Application Data
(60) Provisional application No. 63/681,809, filed on Aug. 10, 2024.

(51) Int. Cl. H01L 25/11; H01L 21/56; H01L 23/00; H01L 23/538; H01L 25/07

(52) U.S. Cl. CPC H01L 25/115; H01L 21/56; H01L 23/5384; H01L 24/05; H01L 24/08; H01L 24/80; H01L 25/072; H01L 2224/05647; H01L 2224/08225; H01L 2224/80895

(57) ABSTRACT

Systems and methods are provided for three-dimensional (3-D) stacking of semiconductor dies in a face-to-back staggered pattern, enabling high-density integration and improved electrical performance in semiconductor assemblies. In one example, hybrid bonding techniques, which incorporate both electrical and mechanical connections, are employed to reliably bond semiconductor die in multiple layers with precise alignment.

### BACKGROUND

### A. Technical Field

The present disclosure relates generally to systems and methods for semiconductor manufacturing. More particularly, the present disclosure relates to systems and methods for three-dimensional (3-D) integration technology, such as for stacking semiconductor dies with high 3-D interconnect density.

### B. Background

The advancement of high-performance computing and telecommunications technologies has driven the demand for innovative semiconductor architectures. Petabit optical switches, which offer unprecedented data transfer rates and processing capabilities, and similar high-speed devices would greatly benefit from a multi-die design that involves hybrid-bonding. Hybrid-bonding incorporates both electrical (e.g., copper-to-copper) and mechanical (e.g., oxide or nitride) connections, enhancing component density and electrical performance by bonding one layer of semiconductor die, also referred to herein as known-good-dies (KGDs), to another.

FIG. 1A through FIG. 1C depict a traditional hybrid bonding process that combines a dielectric (silicon oxide or nitride) bond with embedded metal (e.g., copper) to form interconnections. Initially, a direct bond between the dielectric material (oxide or nitride) is formed at room temperature, as depicted in FIG. 1A. Subsequent heating closes the dishing gap due to the coefficient of thermal expansion (CTE) of metal compared to silicon oxide or nitride. Finally, further heating compresses the metal, e.g., hybrid bonding pads, without external pressure such as to achieve a permanent bond in the integrated product, as depicted in FIG. 1C.

Some semiconductor design and packaging methods bond a top die to two or more adjacent bottom dies, or vice versa, where a bottom die is bonded to two or more adjacent top dies. In a staggered 3-D die stacking, both the top and bottom dies are bonded to multiple adjacent dies in the other layer. The electrical connections between top and bottom dies occur at a fine pitch, currently as low as about 20 μm, using solder-based interconnections. For higher interconnect density and improved signal transmission speeds, a single-digit micron scale pitch based on hybrid bonding interconnections is desirable. However, variations in die thickness inhibit successful hybrid bonding when using existing methods, as hybrid bonding to KGDs requires nanometer-scale flatness at the bonding interface to ensure precise control of bonding surfaces in contact without void. Even minor variations in die thickness can lead to poor contact and bonding quality, compromising the performance and reliability of the final product.

Existing Fan-Out Wafer-Level Packaging (FOWLP) approaches attempt to address coplanarity challenges between dies by using a molding technique to achieve the desired flatness. FOWLP encapsulates the dies in a molding material, which is then planarized to create a flat surface for subsequent processing. However, such approaches suffer from die shift, a significant drawback that occurs due to uncontrolled mold flow during the encapsulation process, causing the dies to move away from their intended positions. These shifts can lead to misalignments of dies with respect of the redistribution layer (RDL) patterns needed to establish proper electrical connections between dies.

Adaptive correction methods that counter die shift by dynamically adjusting the RDL patterns to follow the shifted dies have proven insufficient for achieving the precise alignment required for hybrid bonding and staggered 3-D die stacking. The inherent variability in the mold flow and the subsequent die positions create inconsistencies that cannot be fully compensated, resulting in unreliable bonding interfaces and degraded device performance.

Accordingly, what is needed are systems and methods that overcome existing process challenges and provide improved solutions for achieving the required flatness and precise alignment for effective hybrid bonding in staggered 3-D die stacking.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not drawn to scale.

FIG. 1A through FIG. 1C depict a traditional hybrid bonding process.

FIG. 2A through FIG. 2I illustrate a process for 3-D stacking dies in a staggered pattern according to various embodiments of the present disclosure.

FIG. 3A through FIG. 3I illustrate another process for 3-D stacking dies in a staggered pattern according to various embodiments of the present disclosure.

FIG. 4A through FIG. 4I illustrate yet another process for 3-D stacking dies in a staggered pattern according to various embodiments of the present disclosure.

FIG. 5 through FIG. 8 illustrate alternative embodiments according to various embodiments of the present disclosure.

FIG. 9 illustrates an exemplary three-layer stack according to various embodiments of the present disclosure.

FIG. 10A through FIG. 10D are top views of exemplary multi-die interconnection arrangements according to various embodiments of the present disclosure.

FIG. 11 through FIG. 13 are flowcharts of illustrative processes for 3-D stacking dies in a staggered pattern according to various embodiments of the present disclosure.

FIG. 12 is a flowchart illustrating a process for 3-D stacking dies in a staggered pattern according to various embodiments of the present disclosure.

FIG. 13 is a flowchart illustrating a process for 3-D stacking dies in a staggered pattern according to various embodiments of the present disclosure.

FIG. 14 depicts a partial schematic cross-section of a traditional integrated circuit (IC).

FIG. 15A illustrates a supporting structure comprising a hybrid bonding pad array according to various embodiments of the present disclosure.

FIG. 15A through FIG. 15F illustrate a process for 3-D stacking dies in a staggered pattern according to various embodiments of the present disclosure.

FIG. 15B illustrates KGDs hybrid-bonded to a supporting structure according to various embodiments of the present disclosure.

FIG. 15C illustrates a planarizing step according to various embodiments of the present disclosure.

FIG. 15D illustrates fabricating a routing layer and a hybrid bonding pad array onto the structure shown in FIG. 15C.

FIG. 15E illustrates face-to-back bonding according to various embodiments of the present disclosure.

FIG. 15F illustrates additional steps for producing a structure according to various embodiments of the present disclosure.

FIG. 16A and FIG. 16B illustrate alternative embodiments according to various embodiments of the present disclosure.

FIG. 17 is a flowchart illustrating a face-to-back bonding process for 3-D stacking dies in a staggered pattern according to various embodiments of the present disclosure.

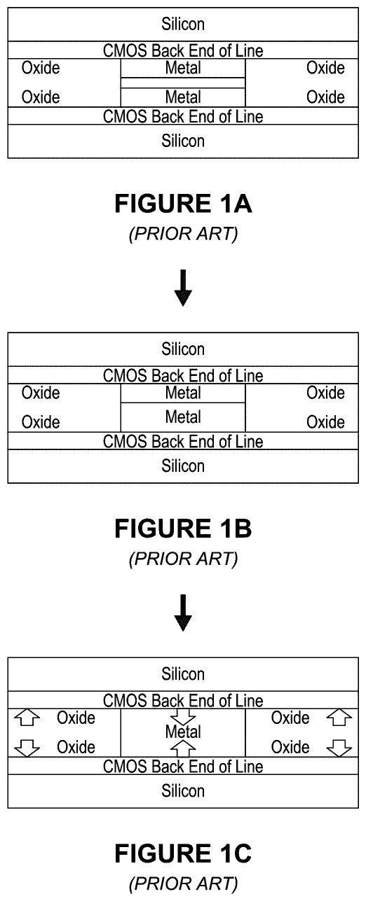

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion components may be described as separate functional units, which may comprise sub-units, but those skilled in the art will recognize that various components, or portions thereof, may be divided into separate components or may be integrated, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgment, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification do not necessarily all refer to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

Systems and methods are provided for three-dimensional (3-D) stacking of semiconductor dies in a face-to-back staggered pattern, enabling high-density integration and improved electrical performance in semiconductor assemblies.

Consistent with the present disclosure, hybrid bonding techniques, which incorporate both electrical and mechanical connections, are employed to reliably bond semiconductor die, also referred to herein, as known-good-dies (KGDs), in multiple layers with precise alignment.

Processes are described for arranging hybrid bonding pad arrays on substrates or supporting structures, bonding semiconductor dies using hybrid or direct dielectric bonding, encapsulating and planarizing the assembly to achieve nanometer-scale flatness, and forming high-density vertical interconnections such as through-silicon vias (TSVs) or thru-encapsulation-vias (TEVs).

The systems may employ supporting structures including interposer substrates with routing layers and TSVs to further enhance mechanical integrity and signal transmission.

Staggered stacking of layers of die or laterally offsetting the die in such layers relative to one another the optional inclusion of dummy dies contribute to mechanical robustness and thermal management.

Consistent with the present disclosure, scalable manufacturing of complex semiconductor stacks with fine-pitch interconnects is provided, supporting advanced computing and telecommunications applications that require high performance and reliability.

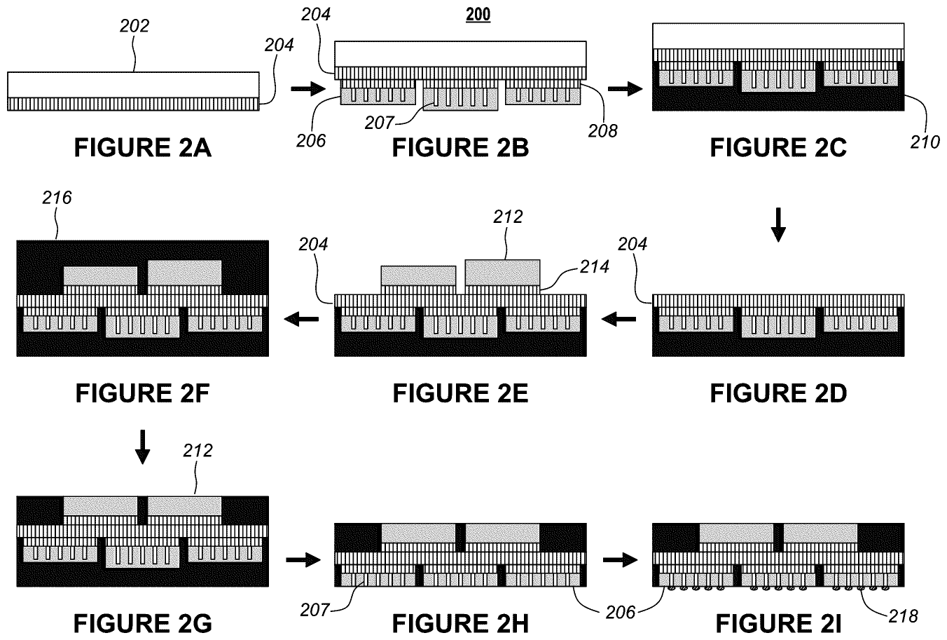

FIG. 2A through FIG. 2I illustrate a process for 3-D stacking dies in a staggered pattern according to various embodiments of the present disclosure. As depicted, process 200 starts with arranging an array of hybrid bond pads (hereinafter “intermediate array”) 204 in a hybrid bond pattern on temporary carrier 202. In embodiments, temporary carrier 202 is used to manufacture a product that comprises bottom KGDs 206 and top KGDs 212, depicted in FIG. 2E. Bottom KGDs 206 comprise, in addition to Through-Silicon Vias (TSVs) 207, hybrid bond pads 208, which in the manufactured product are encapsulated with one or more encapsulating materials 210 (e.g., an epoxy-based molding compound, silicon oxide, or any combination thereof) to create a wafer-like structure that can be processed similarly to a traditional semiconductor wafer. Similarly, top KGDs 212 comprise hybrid bond pads 214 and are encapsulated with encapsulating material 216.

As depicted in FIG. 2A, intermediate array 204 is disposed on temporary carrier 202, which may be fabricated from materials such as glass, silicon, polymers, and the like, and, in embodiments, may be pre-patterned with intermediate array 204. The hybrid bonding pads of intermediate array 204 may comprise electrical pads made from electrically conductive material (e.g., copper) that serve as points of electrical contact and a mechanical medium made from dielectric material (e.g., silicon oxide or silicon nitride) that are interspersed among the electrical pads to serve as points of mechanical contact. It is understood that the hybrid nature of such designs is not limited to any particular material or material combination as hybrid bonding may be implemented, for example, with organic polymer-based materials. It is further understood that pads may comprise alignment marks, which may be strategically placed at the periphery or within pad patterns to ensure that KGDs (e.g., 206) with hybrid bond pad patterns that are configured to match the bonding patterns of the hybrid bond pads of intermediate array 204 correctly align during the alignment step of the bonding process that hybrid-bonds bottom KGDs 206 to temporary carrier 202. As discussed further in greater detail below, intermediate array 204 may comprise routing patterns and/or additional electrical connections, such as metal traces through encapsulation vias that are embedded in encapsulating material 210 and form electrical connections (not shown).

As depicted in FIG. 2B, the bonding pattern of intermediate array 204 matches that of KGDs 206, which are bonded to the bottom side of temporary carrier 202. Hybrid bonding creates a strong and reliable interface between KGDs 206 intermediate array 204. As a result, any die shift in bottom KGDs 206 will be negligible, and the positions of bottom KGDs 206 will be correctly locked in place. It is understood that TSVs 207 represent any vertical interconnections including conductive material through KGDs 206 used for signal transmission, power supply, control command, and the like.

As depicted in FIG. 2C, the wafer structure may be reconstituted, e.g., with encapsulating material 210. In embodiments, a thick (e.g., 30 μm) oxide may be deposited at low temperatures onto bottom KGDs 206 or top KGDs 212 to form encapsulation 210 or 216 respectively, by using any deposition method known in the art. Compared to common molding materials, oxide is known to be less prone to limitations posed by temperature-induced shrinkage caused by the large CTE of common molding materials, which may impact the yield and reliability of the hybrid bonding process. At this point, the wafer structure comprises individual KGDs 206 embedded in encapsulating material 210, which fills the spaces between KGDs 206.

As depicted in FIG. 2D, temporary carrier 202 may be removed by using a carrier debond, backgrinding, or etching process followed by any planarization process known in the art, such as chemical-mechanical polishing (CMP) or electrochemical planarization (ECP), thereby exposing the hybrid bonds of intermediate array 204.

As depicted in FIG. 2E, top KGDs 212 are then hybrid-bonded to the bond pads of intermediate array 204 to achieve hybrid bonding on both sides of intermediate array 204. Once the positions of both top KGDs 212 and bottom KGDs 206 are locked in place, top KGDs 212 may be encapsulated with one or more encapsulating materials 210, as depicted in FIG. 2F. This may be achieved, for example, by using a gap-fill process, an overmolding process, or by covering top KGDs 212 with thick oxide at low temperatures, e.g., to prevent inter-metal melting and diffusion of implanted dopants during subsequent high-temperature processing steps.

As depicted in FIG. 2G, the upper portions of top KGDs 212 may be flattened, e.g., by a planarization process that creates a flat and uniform surface. It is noted that, although not expressly discussed in detail herein, various embodiments may comprise any number of additional steps to achieve the objectives of the present disclosure, such as surface preparation steps. As an example, a cleaning process that removes contaminants, which otherwise may interfere with the bonding process, may be applied following a planarization step.

As depicted in FIG. 2H, the backsides of bottom KGDs 206 may be thinned and flattened to reveal TSVs 207. Finally, as depicted in FIG. 2I, one or more Under Bump Metallization (UBM) layers may be deposited on the contact pads of KGDs 206, onto which then solder bumps 218 may formed, for example, by using any copper pillar solder capped micro bump plating known in the art. A surface finishing process may prepare the final structure for die attachment to corresponding solder bumps or pads.

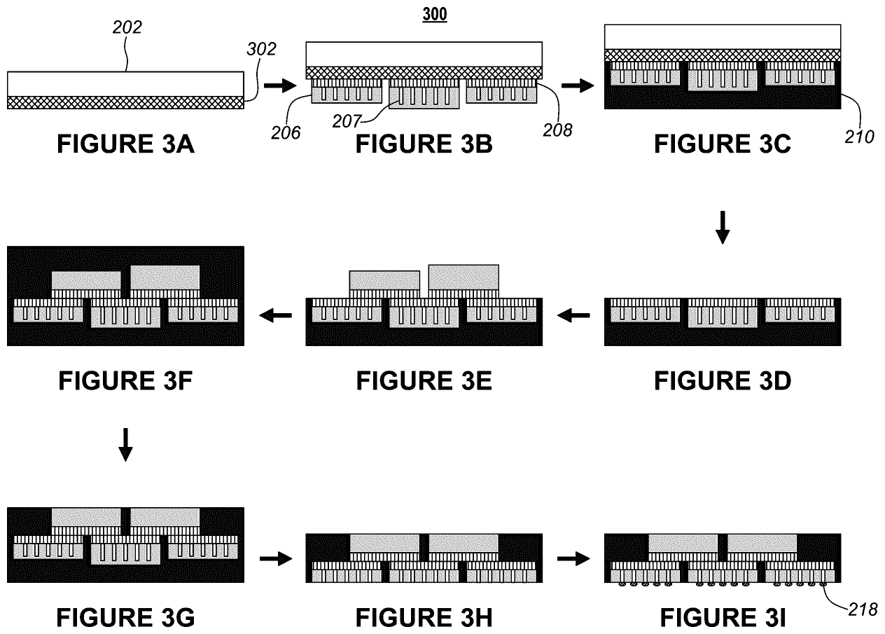

FIG. 3A through FIG. 3I illustrate another process for 3-D stacking dies in a staggered pattern according to various embodiments of the present disclosure. For clarity, components similar to those shown in FIG. 2A through 2I are labeled in the same manner. For purposes of brevity, a description or their function is not repeated here. FIG. 3A depicts a temporary carrier 202 onto which dielectric layer 302 (e.g., silicon oxide or silicon nitride) is deposited, e.g., by a chemical vapor deposition process. In embodiments, dielectric layer 302 comprises alignment marks (not shown) that ensure the correct positioning of KGDs 206. In these embodiments, instead of utilizing a hybrid bond pattern as previously described with reference to FIG. 2A to FIG. 2I, bottom KGDs 206 in FIG. 3B are bonded onto dielectric layer 302, for example, by using a direct oxide/nitride bonding process. It is understood that a suitable bonding process may comprise activating and annealing steps, such as in-situ plasma pre-treatment, low-temperature annealing, and the like, to provide sufficient bond strength to ensure that the respective surfaces dielectric layer 302 and hybrid bond pads of bottom KGDs 206 are reliably connected.

As depicted in FIG. 3D, both temporary carrier 202 and dielectric layer 302 are then removed, thereby exposing bottom hybrid bond pads of KGDs 206 before top KGDs 212 are hybrid-bonded to the hybrid bond pads of bottom KGDs 206, as depicted in FIG. 3E.

FIG. 3F through FIG. 3I depict manufacturing steps similar to those previously discussed with reference to FIG. 2F to FIG. 2I. For brevity, these steps are summarized as follows: the wafer structure is reconstituted with encapsulating material and planarized to create a flat top surface. Then, UBM layers onto which solder bumps 218 can be formed may be deposited. It is noted that, unlike in process 200, the material layer in contact with temporary carrier 202 in process 300, which provides an alignment, is removed during the process 300.

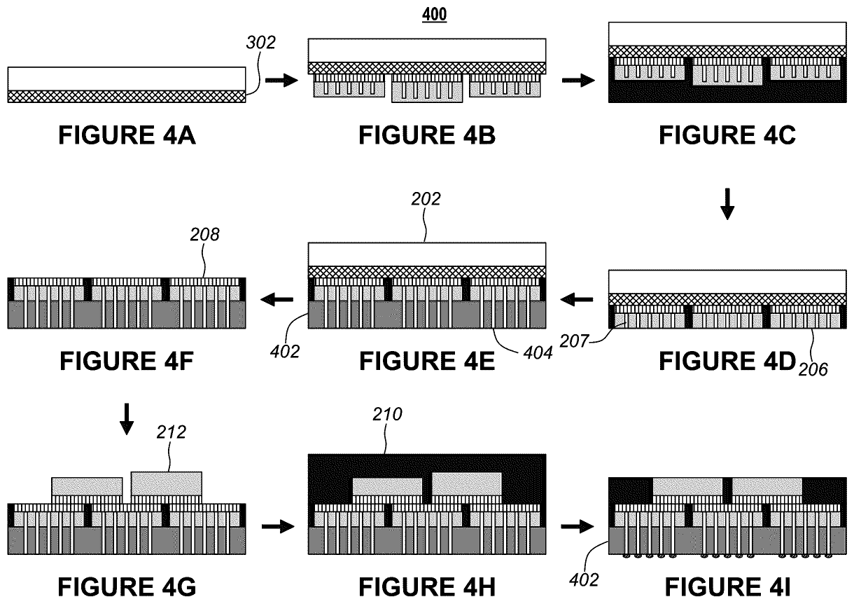

FIG. 4A through FIG. 4I illustrate yet another process for 3-D stacking dies in a staggered pattern according to various embodiments of the present disclosure. FIG. 4A to FIG. 4C are substantially similar to the manufacturing steps discussed with reference to FIG. 3A through FIG. 3C. Same numerals denote similar elements.

As shown in process 400, prior to performing a CMP step that removes temporary carrier 202 to expose hybrid bond pads 208 of bottom KGD, depicted in FIG. 4F, bottom KGDs 206 may be thinned and flattened after backgrinding encapsulating material 210 by a planarization process, as depicted in FIG. 4D, to expose TSVs 207 of bottom KGDs 206. This prepares the structure for hybrid bonding to TSVs 404 of supporting structure 402, which may be implemented as a relatively thick interposer or interposer substrate (e.g., 300 μm or thicker) made of silicon, organic materials, ceramic, or glass, as depicted in FIG. 4E. In embodiments, this step replaces encapsulating material 210 with a physical structure that exhibits superior mechanical strength properties.

Advantageously, this substitution prevents potential deformations caused by warping of molding material 210 and enhances the overall stability of the assembly. In embodiments, supporting structure 402 may serve the functions of a wafer substrate. It is understood that TSVs 404 in interposer substrate 402 may manufactured from solid metal, e.g., electroplated copper, or be metal-coated (e.g., using a metal coating, such as copper that lines the walls of each via) or hollow (unfilled or filled with a filling material, such as an insulating or supportive material, e.g., polymer) as illustrated in FIG. 8.

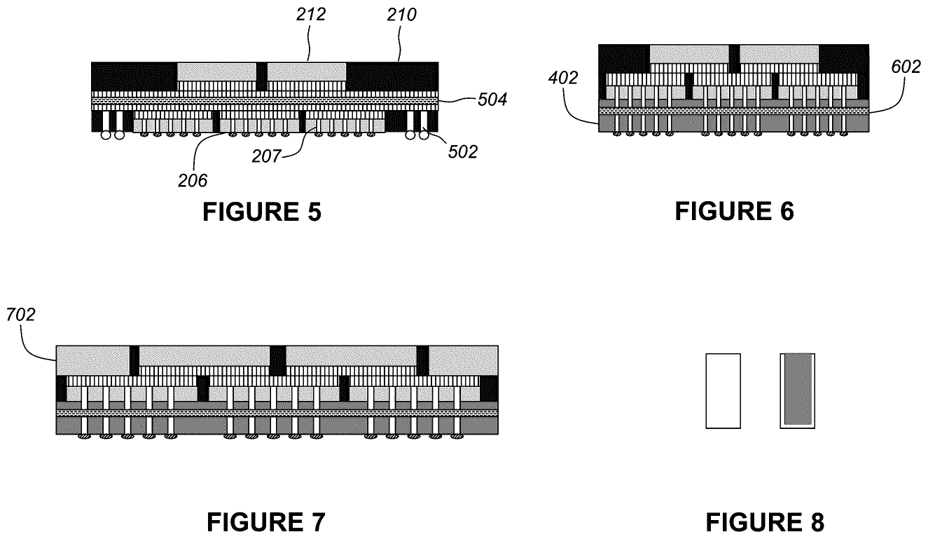

FIG. 4G through FIG. 4I of process 400 correspond to FIG. 3E to FIG. 3G for process 300. For brevity, the detailed steps are summarized as follows: the wafer structure is finalized with hybrid bonding of top KGDs 212 to the exposed bond pads of bottom KGDs 206, encapsulated with encapsulating material 210, and planarized to create a flat surface. The final structure, depicted in FIG. 4I, constitutes a 3-D stack of staggered dies on top of supporting structure 402 comprising TSVs 404, providing a robust and high-performance semiconductor assembly. It is understood that, in embodiments, a supporting structure such as supporting structure 402 may also be added to the structures shown in FIG. 31, FIG. 4I, and FIG. 5.

As depicted in FIG. 5, in embodiments, thru-encapsulation-vias (TEVs) 502, which pass through encapsulating material 210, provide pathways for electrical connections, such as power and ground connections. Utilizing TEVs 502 in this manner offers significant advantages as it frees up TSVs 207 in bottom KGDs 206 and allows TSVs 207 to be dedicated exclusively to signal transmission. Additionally, these embodiments help to avoid placing TSVs 207 in sensitive high-speed serializer/deserializer circuits, thereby enhancing overall performance and reliability. In embodiments, routing layer 504 may be placed within intermediate array 204 to provide horizontal interconnects, for example, connecting TEV 502 to bottom KGDs 206 or top KGDs 212.

As depicted in FIG. 6, in embodiments, to address limitations that might arise from design or process constraints, re-routing layers 602 may be placed on either side or both sides of supporting structure 402, here a relatively thick interposer substrate, e.g., to convert a bonding pad array into a TSV array.

As depicted in FIG. 7, in embodiments, any number of dummy dies 702 that need not comprise any active circuitry may be incorporated into one or more layers above supporting structure 402. Advantageously, dummy dies 702 enhance mechanical integrity by strengthening the stacked structure, providing additional support and stability, especially in multi-layer designs. Further, dummy dies 702 help in distributing mechanical stress evenly across an assembly, thereby reducing the risk of warping or deformation. Moreover, acting as thermal conductors, dummy dies 702 may dissipate heat from nearby active dies such as to maintain consistent temperatures within a stacked structure, thus improving thermal management.

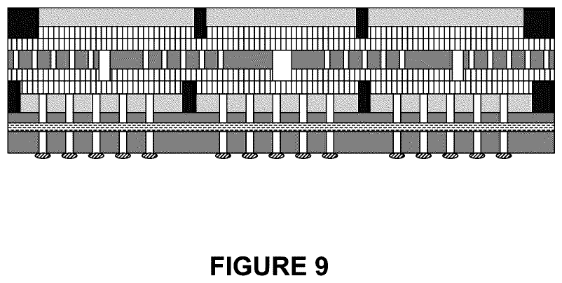

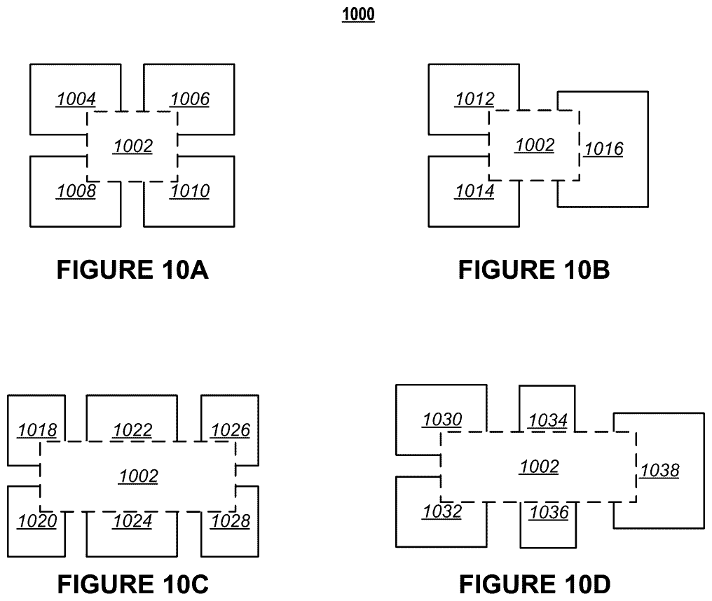

FIG. 9 illustrates an exemplary three-layer stack according to various embodiments of the present disclosure. It is understood that any number of layers comprising KGDs may be sequentially bonded using the hybrid bonding techniques presented herein. In this manner, a multi-layer 3-D stack of staggered KGDs may be constructed while ensuring consistent alignment and reliable interconnections across all layers. Advantageously, such staggered arrangements of dies enhance the electrical performance of a stack and allow for scalable manufacturing, which enables the manufacture of complex 3-D stacks having high integration density. FIG. 10A through FIG. 10D are top views of exemplary multi-die interconnection arrangements between adjacent layers in a 3-D stack according to various embodiments of the present disclosure. Die 1002 in FIG. 10A through FIG. 10D represents a die in one layer and dies 1004-1038 represent dies in a layer adjacent to die 1002. In embodiments, die 1002 and dies 1004-1010 interconnect using one or more hybrid bonding systems and methods mentioned herein, as shown in FIG. 10A. Similarly, as shown in FIG. 10B, die 1002 and dies 1012-1016 interconnect, and so on.

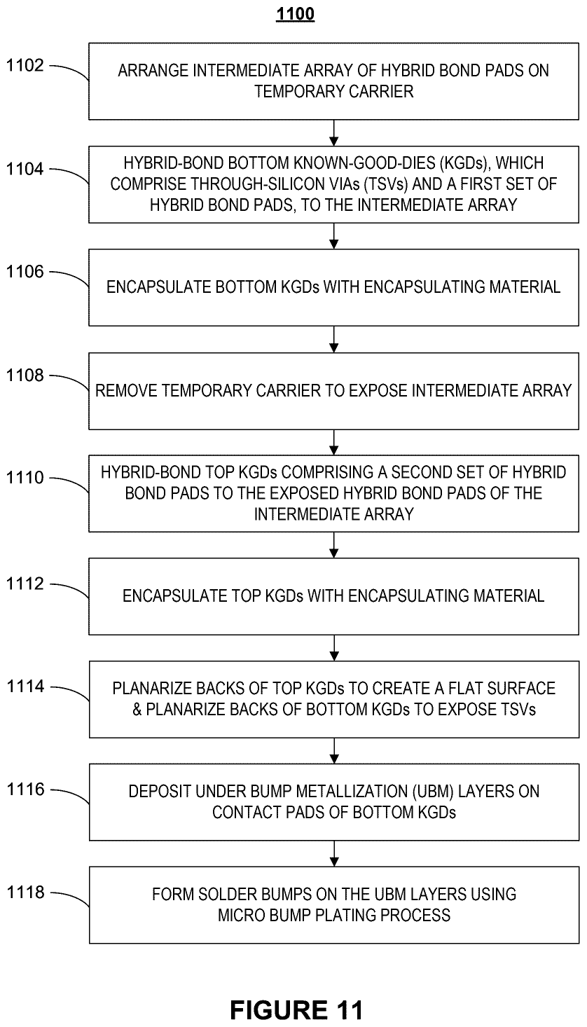

FIG. 11 is a flowchart illustrating a process for 3-D stacking dies in a staggered pattern according to various embodiments of the present disclosure. Process 1100 may begin, when at step 1102, an intermediate array of hybrid bond pads is arranged on a temporary carrier. The temporary carrier that may comprise glass or silicon.

At step 1104, a set of bottom KGDs, which comprises TSVs and a first set of hybrid bond pads, is hybrid-bonded to the intermediate array.

At step 1106, the bottom KGDs are encapsulated with encapsulating material, such as an epoxy-based molding material, silicon oxide, or any combination thereof.

At step 1108, the temporary carrier is removed, e.g., using a planarization process to expose the intermediate array.

At step 1110, the top KGDs, which comprise a second set of hybrid bond pads, are hybrid-bonded to the exposed hybrid bond pads of the intermediate array.

At step 1112, the top KGDs are encapsulated with encapsulating material.

At step 1114, the backs of the top KGDs are planarized to create a flat surface and the backs of the bottom KGDs are planarized to expose their TSVs.

At step 1116, one or more UBM layers are deposited on contact pads of the bottom KGDs.

At step 1118, solder bumps are formed on the UBM layers, e.g., by using a micro bump plating process.

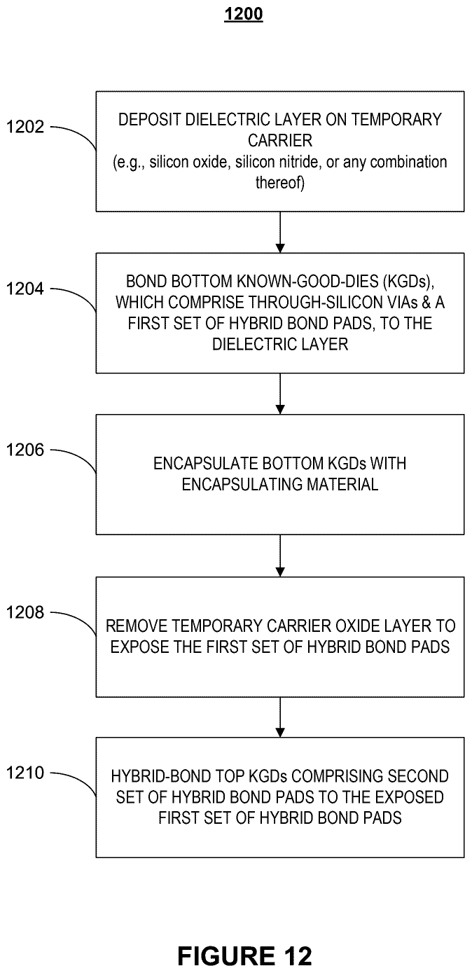

FIG. 12 is a flowchart illustrating a process for 3-D stacking dies in a staggered pattern according to various embodiments of the present disclosure. Process 1200 may begin, when at step 1202, a dielectric layer, such as silicon oxide or silicon nitride, or any combination thereof, is deposited on a temporary carrier that may comprise glass or silicon.

At step 1204, a set of bottom KGDs, which comprises TSVs and a first set of hybrid bond pads, is bonded to the dielectric layer.

At step 1206, the bottom KGDs are encapsulated with encapsulating material, such as an epoxy-based molding material, silicon oxide, or any combination thereof.

At step 1208, the temporary carrier is removed, e.g., using a planarization process to expose the first set of hybrid bond pads.

At step 1210, the top KGDs, which comprise a second set of hybrid bond pads, are hybrid-bonded to the exposed first set of hybrid bond pads.

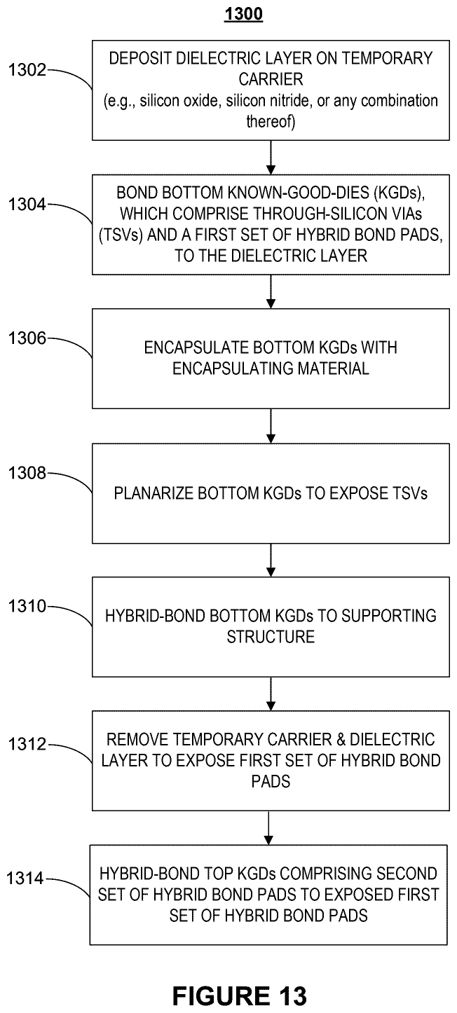

FIG. 13 is a flowchart illustrating a process for 3-D stacking dies in a staggered pattern according to various embodiments of the present disclosure. Process 1300 may begin, when at step 1302, a dielectric layer, such as silicon oxide, silicon nitride, or any combination thereof, is deposited on a temporary carrier that comprises material comprising, e.g., glass, silicon, polymer, etc.

At step 1304, a set of bottom KGDs, which comprises TSVs and a first set of hybrid bond pads, is bonded to the dielectric layer.

At step 1306, the bottom KGDs are encapsulated with encapsulating material, such as an epoxy-based molding material, silicon oxide, or any combination thereof.

At step 1308, the bottom KGDs are planarized to expose the TSVs.

At step 1310, the bottom KGDs are hybrid-bonded to a supporting structure such as a thick interposer substrate made of silicon, organic materials, ceramic, or glass and comprising TSVs.

At step 1312, the temporary carrier and the dielectric layer are removed to expose the first set of hybrid bond pads.

At step 1314, the top KGDs comprising a second set of hybrid bond pads are hybrid-bonded to the exposed first set of hybrid bond pads.

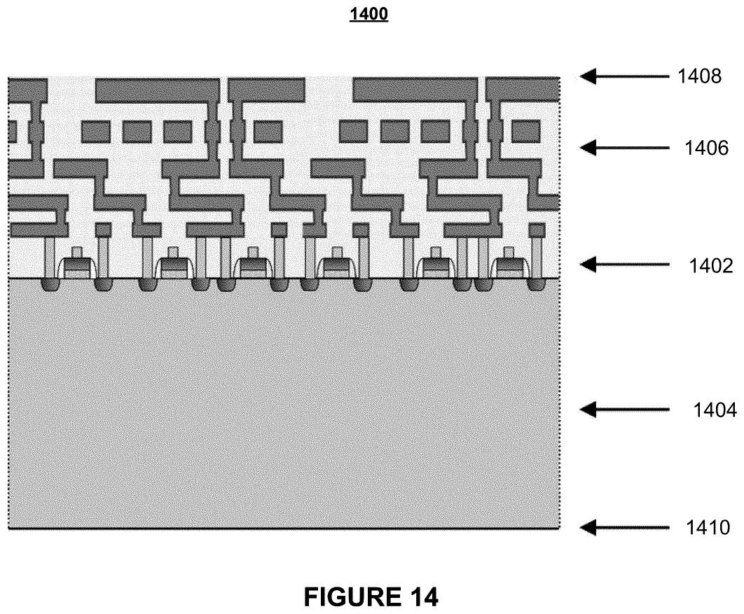

FIG. 14 depicts a partial schematic cross-section of a traditional IC. IC 1400 typically comprises electric components 1402, such as diodes, transistors, and passive components that are disposed on bulk silicon material 1404 of a common silicon wafer. As shown in FIG. 14, five metal layers 1406 or routing layer, for example, provide access to transistors 1402 and interconnect them electrically. For purposes of discussion, top surface 1408 of the layer comprising transistors 1402 is herein also referred to as “face,” “front,” or “front side.” Contrariwise, surface 1410 of the layer comprising bulk silicon 1404 is herein referred to as “back” or “backside.” In one example, transistors 1402 are provided on the front side of the semiconductor die, as noted above in regard to FIG. 14.

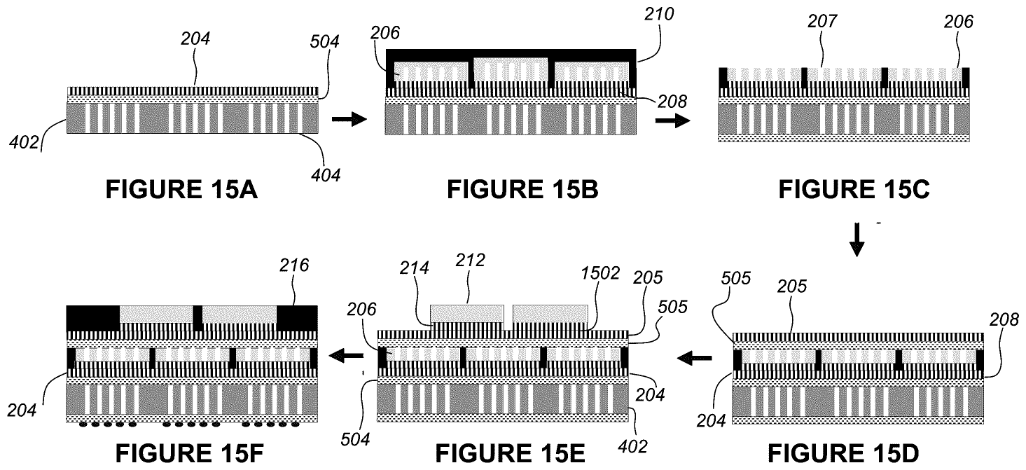

FIG. 15A illustrates a supporting structure comprising a hybrid bonding pad array according to various embodiments of the present disclosure. As for example in FIG. 6 and FIG. 7, supporting structure 402 may be implemented as a relatively thick interposer substrate, such as an interposer wafer. As depicted in FIG. 15A, supporting structure 402, which may comprise TSVs 404, comprises routing layer 504, and a plurality of first conductors, such as hybrid bonding pad array 204. It is noted that, in embodiments, supporting structure 402 may comprise routing layers 504 on either side or both sides. In addition, supporting structure 402 may be a substrate.

FIG. 15B illustrates KGDs hybrid-bonded to a supporting structure according to various embodiments of the present disclosure. As depicted, bottom KGDs 206 are placed face-down onto supporting structure 402 before being encapsulated by encapsulating material 210.

FIG. 15C illustrates a planarizing step according to various embodiments of the present disclosure. As depicted planarization is used to remove encapsulating material 210 to thin and flatten the backsides of bottom KGDs 206 such as to reveal TSVs 207 including conductors (a second plurality of conductors) of bottom KGDs 206.

FIG. 15D illustrates fabricating a routing layer and a hybrid bonding pad array onto the structure shown in FIG. 15C. It is understood that while two routing layers 504 and 505 and two hybrid bonding pad arrays 204 and 205 are shown in FIG. 15D, this is not intended as a limitation on the scope of the present disclosure. As an example, as with the optional routing layer shown in FIG. 9, supporting structure 402 in FIG. 15D may comprise any number of routing layers.

FIG. 15E illustrates face-to-back bonding according to various embodiments of the present disclosure. In embodiments, top KGDs 212 comprise hybrid bond pads 214 that are hybrid-bonded face-down on top of routing layer 505 to interface with hybrid bonding pad array 205. Interface 1502 between hybrid bonding pad array 205 and hybrid bond pads 214 constitutes a face-to-back bond that differs from traditional face-to-face bonds, which are typically formed between top KGDs and bottom KGDs. Moreover, unlike the face-to-back bonding between KGDs and support structures illustrated in FIG. 9, face-to-back bond in FIG. 15E constitutes a hybrid-bond between the front of top KGD 212 and the back of bottom KGD 206. In addition, as shown in FIG. 15E, hybrid bond pads 208 on the front of bottom KGD 206 are hybrid-bonded to hybrid bond pads 204 support structure 402.

In one example, shown in FIG. 15E, KGDs 212 are staggered or laterally offset relative to KGDs 206.

FIG. 15F illustrates additional steps for producing a structure according to various embodiments of the present disclosure. Exemplary steps may comprise encapsulating top KGDs 212 with encapsulating material 216 and grinding encapsulating material 216 down to obtain a flat and uniform surface.

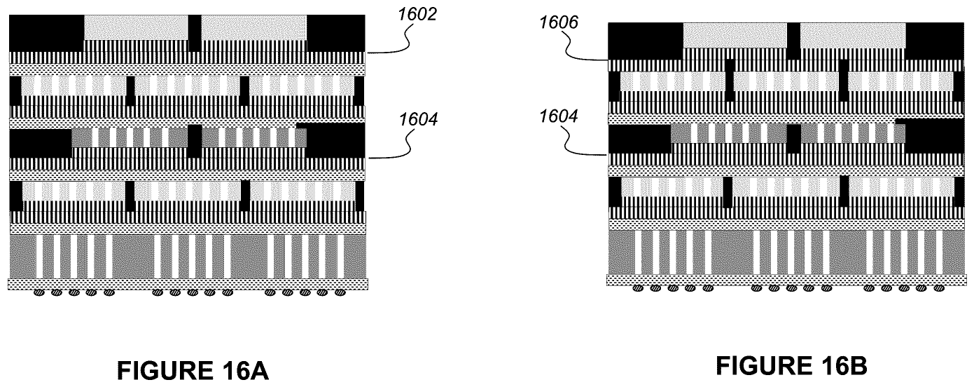

FIG. 16A and FIG. 16B illustrate alternative embodiments according to various embodiments of the present disclosure. As shown in FIG. 16A, in embodiments, any number of face-to-back 1502, 1504 layers may be used to fabricate a 3D structure according to the teachings herein. Further, in embodiments, as shown in FIG. 16B, any number of layers comprising face-to-back bonding 1504 may be combined with layers comprising face-to-face bonding 1506.

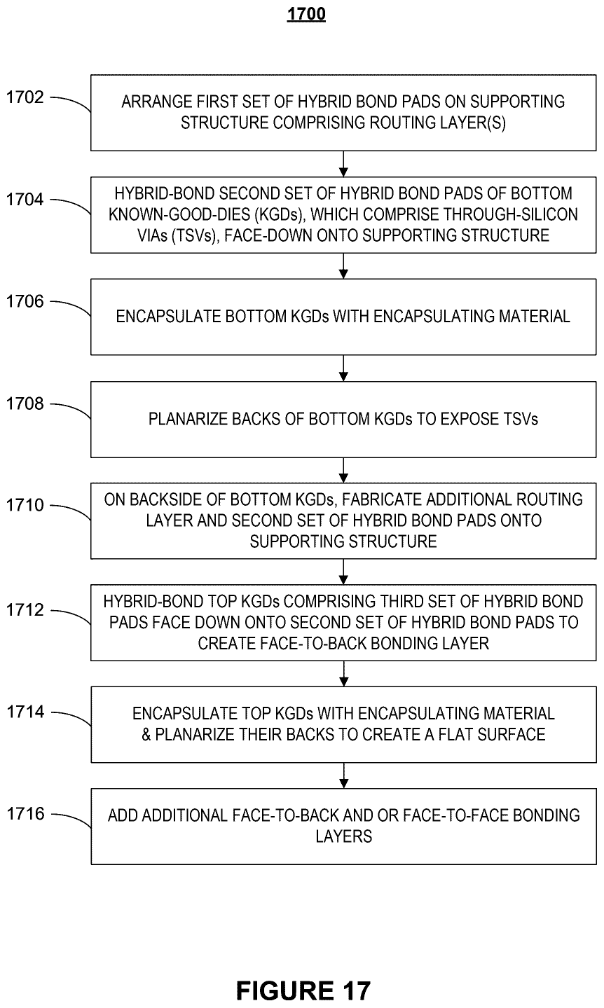

FIG. 17 is a flowchart illustrating a face-to-back bonding process for 3-D stacking dies in a staggered pattern according to various embodiments of the present disclosure. In embodiments, process 1700 may begin, when at step 1702 an intermediate array of hybrid bond pads is arranged on a supporting structure. The supporting structure may comprise materials such as silicon, organic materials, ceramic, or glass and at least one routing layer.

At step 1704, a set of bottom KGDs, which comprises TSVs and a first set of hybrid bond pads, is hybrid-bonded face-down onto the supporting structure comprising the routing layer.

At step 1706, the bottom KGDs are encapsulated with encapsulating material, such as an epoxy-based molding material, silicon oxide, or any combination thereof.

At step 1708, the encapsulated bottom KGDs are planarized to expose their TSVs.

At step 1710, on the backside of the bottom KGDs, a routing layer and an additional hybrid bonding pad array is fabricated onto the structure.

At step 1712, top KGDs, which comprise hybrid bond pads, are hybrid-bonded face-down onto the routing layer of the supporting structure to create a face-to-back stacked structure.

At step 1714, the top KGDs are encapsulated with encapsulating material and their backs are planarized to create a flat and uniform surface.

At step 1716, additional face-to-back and/or face-to-face bonding layers may be added, depending on design requirements, to achieve a multi-layer 3-D stack.

As a result, embodiments allow for the fabricating of complex, high-density 3-D stacked semiconductor assemblies with enhanced mechanical integrity and electrical performance.

One skilled in the art shall recognize that: (1) certain steps may optionally be performed; (2) steps may not be limited to the specific order set forth herein; (3) certain steps may be performed in different orders; and (4) certain steps may be done concurrently.

One skilled in the art will recognize no computing system or programming language is critical to the practice of the present disclosure. One skilled in the art will also recognize that a number of the elements described above may be physically and/or functionally separated into modules and/or sub-modules or combined.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

What is claimed is:

1. An apparatus, comprising:
a substrate having a surface;
a plurality of conductors being provided on the surface of the substrate;
a first plurality of semiconductor die, each of which having a front and a back, wherein the front is opposite the back, a first plurality of transistors being provided on the front of each of the first plurality of semiconductor die, such that the front of each of the first plurality of semiconductor die faces the substrate, a first plurality of electrical connections connecting the first plurality of transistors to the plurality of conductors on the surface of the substrate;
a second plurality of semiconductor die provided on the first plurality of semiconductor die, such that the second plurality of semiconductor die is offset relative to the first plurality of semiconductor die, each of the second plurality of semiconductor die having a second plurality of transistors provided on the front of each of each of the second plurality of semiconductor die, such that the front of each of the second plurality of semiconductor dies faces the back of each of the first plurality of semiconductor die;
a second plurality of electrical connections that connect the first plurality of transistors to the second plurality of transistors, the second plurality of electrical connections extending through the first plurality of semiconductor die.

2. An apparatus in accordance with claim 1, wherein the substrate is an interposer substrate.

3. An apparatus in accordance with claim 1, wherein the second plurality of electrical connections includes through silicon vias (TSVs).

4. An apparatus in accordance with claim 1, wherein the plurality of first electrical connections includes bonding pads provided on substrate.

5. An apparatus in accordance with claim 4, wherein the bonding pads includes hybrid bonding pads.

6. An apparatus in accordance with claim 1, wherein the plurality of first electrical connections includes a routing layer provided on the substrate.

7. An apparatus in accordance with 1, wherein the first plurality of electrical connections includes a first routing layer, and the second plurality of electrical connections includes a second routing layer.

8. An apparatus in accordance with claim 1, wherein the first plurality of electrical connections includes a first routing layer and first bonding pads, and the second plurality of electrical connections includes a second routing layer and second bonding pads.

9. An apparatus in accordance with claim 1, further including an encapsulating material, the first plurality of semiconductor die being embedded in the encapsulating material.

10. An apparatus in accordance with claim 1, wherein the plurality of first electrical connections and the plurality of second electrical connections includes copper.

11. An apparatus, comprising:
an interposer including a first surface;
a first array of bonding pads disposed on the first surface of the interposer;
a plurality of first semiconductor die, each first semiconductor die comprising a plurality of through-silicon vias and a second array of bonding pads on a first side of each of the plurality of first semiconductor die, wherein the first side of each of the plurality of first semiconductor die is provided facing the first array of bonding pads of the interposer, such that the first array of bonding pads contacts the second array of bond pads; and
a plurality of second semiconductor dies, each of the second plurality of semiconductor die comprising a third array of bonding pads provided on a side of each of the plurality of second semiconductor die facing the first plurality of semiconductor die, such that the third array of bonding pads is electrically connected to the second array of bonding pads by conductor paths including the through silicon vias.

12. The apparatus of claim 11, wherein the interposer further comprises:
a plurality of through-silicon vias extending through the interposer.

13. The apparatus of claim 12, wherein the interposer further comprises:
at least one routing layer positioned between the first array of bonding pads and the plurality of through-silicon vias.

14. The apparatus of claim 11, wherein each of the first plurality of semiconductor die is at least partially encapsulated in an encapsulation material.

15. The apparatus of claim 14, wherein the encapsulation material is planarized to expose a surface of the each of the first plurality of semiconductor die.

16. The apparatus of claim 11, wherein the interposer comprises:
a material selected from the group consisting of silicon, organic material, ceramic, and glass.

17. The apparatus of claim 12, wherein the at least one routing layer is a first routing layer, the interposer further including a second routing layer provided on another side of the interposer opposite the first routing layer.

18. A method, comprising:
providing a first plurality of bonding pads on a substrate;
bonding a second plurality of bonding pads onto the first plurality of bonding pads, the second plurality of bonding pads being provided on a first surface of each of a first plurality of semiconductor die;
encapsulating the first plurality of die with a first encapsulating material;
planarizing the encapsulating material to expose a second surface of each of the first plurality of semiconductor die, the second surface of each of the first plurality of semiconductor die being provided opposite the first surface of each of the first plurality of semiconductor die;
providing a routing layer on the second surface of each of the first plurality of semiconductor die;
providing a second plurality of bonding pads on the routing layer;
bonding a third plurality of bonding pads onto the second plurality of bonding pads, the third plurality of bonding pads being provided a first surface of a second plurality of semiconductor die;
encapsulating the second plurality of semiconductor die with a second encapsulating material; and
planarizing the second encapsulating material to expose a second surface of each of the second plurality of semiconductor die, the second surface of each of the second plurality of semiconductor die being opposite the first surface of each the second plurality of semiconductor die.

19. A method in accordance with claim 18, further including a step of forming a plurality of through silicon vias in each of the first plurality of semiconductor die, the plurality of through silicon vias being filled with conductive material to electrically connect the second plurality of bonding pads to the first plurality of bonding pads.

20. A method in accordance with claim 18, wherein the step of bonding a second plurality of bonding pads onto the first plurality of bonding pads includes first hybrid bonding step and the step of bonding a third plurality of bonding pads onto the second plurality of bonding pads including a second hybrid bonding step.
